(19) United States
(12) Patent Application Publication
(10) Pub. No.: US 2019/0366460 A1
(43) Pub. Date: Dec. 5, 2019

(54) SOLDERING APPARATUS AND SOLDER NOZZLE MODULE THEREOF

(71) Applicant: PROGRESS Y&Y CORP., New Taipei City (TW)

(72) Inventor: Ming-Chih CHI, New Taipei City (TW)

(21) Appl. No.: 15/995,703

(22) Filed: Jun. 1, 2018

(51) Int. Cl. B23K 3/06; H05K 3/34; B23K 3/08

(52) U.S. Cl. CPC B23K 3/0653; B23K 2201/42; B23K 3/087; H05K 3/3457

(57) ABSTRACT

A soldering apparatus and solder nozzle module thereof are provided. In one embodiment, the soldering apparatus includes a rectangular base; a plurality of columns disposed on edges of the base; a lower heating module vertically disposed through the base; a spooling mechanism disposed on both the base and the lower heating module; a belt conveyor mechanism disposed on the base and under the spooling mechanism; a movement mechanism moveably disposed on the columns at one side of the base and the columns at the other side of the base; and a solder nozzle module having two sides supported by the movement mechanism and disposed through the spooling mechanism to be disposed on the lower heating module.

### BACKGROUND OF THE INVENTION

### 1. Field of the Invention

The invention relates to soldering apparatuses and more particularly to a soldering apparatus and solder nozzle module thereof, the solder nozzle module including a plurality of solder nozzles arranged in rows with improved characteristics.

### 2. Description of Related Art

Consumer electronics are characterized by lightweight, thinness, compactness and flexibility. Consumer electronics incorporate many very small elements and flexible elements. Also, density of the very small elements and flexible elements is very high. How to adhering melted solder to and connecting electronic components together is an issue of soldering electronic circuits to be addressed. It is known that pulse soldering apparatuses have quality solder effect and are widely used.

The present inventor is the patentee of Taiwan Invention Patent No. 1379726, entitled “high speed soldering apparatus and method of using same”, which is characterized by a high performance high speed soldering apparatus and method of using the same by employing a moveable pulse based soldering module for improving the manufacturing process of electronic products. The soldering apparatus comprises a base, a belt conveyor mechanism, a soldering module, a movement mechanism, and a control device. The soldering module includes, from bottom to top, a pulse soldering electrode assembly, a heat sink, a horizontal adjustment module, an activation module, and a transformer module. The movement mechanism includes two parallel longitudinal rails provided on both sides of the top of the base respectively, a plurality of transverse rails corresponding to each soldering module and disposed between the longitudinal rails, a plurality of transverse devices connected to the transverse rails and the longitudinal rails respectively, and a plurality of longitudinal devices disposed at a joining portion of each soldering module and the transverse rail, and adapted to hang each soldering module under the transverse rails.

Taiwan Utility Model No. M396200, entitled “Improved soldering module and high speed soldering apparatus thereof”, is characterized by a high performance, modularized, moveable soldering module and a high speed soldering apparatus thereof. The soldering module includes, from bottom to top, a pulse soldering electrode assembly, a heat sink disposed externally of the pulse soldering electrode assembly, a horizontal adjustment module disposed on a top of the heat sink, an activation module disposed on a top of the horizontal adjustment module and adapted to move the pulse soldering electrode assembly, the heat sink and the horizontal adjustment module along Z-axis back and forth, and a transformer module disposed on a top of the activation module and electrically connected to the pulse soldering electrode assembly.

While the conventional art provide a plurality of solder nozzles for high speed soldering operations, the number of the solder nozzles and density are limited, and wiring of adjacent circuitry is adversely affected. This is because the conventional art has the following drawbacks: It does not tailor to the needs of updated, versatile and complicated circuitry and electronic component soldering. The solder nozzles are hanged under the movement mechanism. The arrangement of the solder nozzles is restricted.

Thus, it is desirable of providing improvements related to the number of solder nozzles, its arrangement and adjustment for alignment so as to tailor to the needs of high density, high precision, and quick soldering operation. Therefore, the present inventor dedicates to invent a soldering apparatus and solder nozzle module thereof having the advantages of being novel, having improved solder nozzle module for the soldering apparatus, and increasing precision, density and efficiency in a soldering operation.

### SUMMARY OF THE INVENTION

It is therefore one object of the invention to provide a solder nozzle module of a soldering apparatus, the solder nozzle module having increase solder nozzles, increased solder nozzle density, and increased positioning precision.

For achieving above and other objects, a first aspect of the invention provides a solder nozzle module disposed on a movement mechanism of a soldering apparatus, comprising a frame secured to the movement mechanism and including at least two parallel bars, and a plurality of solder nozzles disposed under each bar; a plurality of positioning holes arranged in rows and disposed on each solder nozzle; and a plurality of adjustment members each disposed on the solder nozzle and besides the bar, each adjustment member including a fastening elements set secured to the positioning holes.

The first aspect of the invention has the following advantages and benefits in comparison with the conventional art: the number of the solder nozzles and density thereof are increased greatly because the solder nozzles are arranged in a plurality of rows on the frame. Further, positions of the solder nozzles relative to the bar can be quickly adjusted because the fastening elements set is secured to the positioning holes. Furthermore, the solder nozzle module can be assembled or disassembled quickly. In addition, a simple disassembly of the solder nozzle module can detach all solder nozzles from the solder nozzle module. In comparison with the prior art of detaching solder nozzles hanged from the movement mechanism, the invention greatly increases the disassembly efficiency.

Preferably, each adjustment member further comprises a first adjustment seat formed with the fastening elements set, a first fine adjustment element disposed on the first adjustment seat, a second adjustment seat secured to the solder nozzles, and a second fine adjustment element secured to both the second adjustment seat and the first adjustment seat; and wherein the first fine adjustment element is configured to move along X-axis and the second fine adjustment element is configured to move along Y-axis respectively.

The solder nozzle module of the first aspect of the invention implements the following: the first fine adjustment element is configured to move along X-axis for fine adjustment of the solder nozzles, and the second fine adjustment element is configured to move along Y-axis for fine adjustment of the solder nozzles respectively. As an end, each solder nozzle can quickly, precisely move on a horizontal plane in an adjustment operation.

Preferably, each solder nozzle includes a pulse soldering electrode assembly.

It is another object of the invention to provide a soldering apparatus having a modularized solder nozzle module for quick assembly.

For achieving above and other objects, a second aspect of the invention provides a soldering apparatus comprising a rectangular base; a plurality of columns disposed on edges of the base; a lower heating module vertically disposed through the base; a spooling mechanism disposed on both the base and the lower heating module; a belt conveyor mechanism disposed on the base and under the spooling mechanism; a movement mechanism moveably disposed on the columns at one side of the base and the columns at the other side of the base; and a solder nozzle module having two sides supported by the movement mechanism and disposed through the spooling mechanism to be disposed on the lower heating module; wherein the solder nozzle module includes a frame secured to the movement mechanism and including at least two parallel bars, and a plurality of solder nozzles disposed under each bar; a plurality of positioning holes arranged in rows and disposed on each solder nozzle; and a plurality of adjustment members each disposed on the solder nozzle and besides the bar, each adjustment member including a fastening elements set secured to the positioning holes.

The soldering apparatus of the second aspect of the invention has the following advantages and benefits in comparison with the conventional art: positions of the solder nozzles relative to the bar can be quickly adjusted because the fastening elements set is secured to the positioning holes. Further, the solder nozzle module can be assembled or disassembled quickly. Furthermore, a simple disassembly of the solder nozzle module can detach all solder nozzles from the solder nozzle module. In comparison with the prior art of detaching solder nozzles hanged from the movement mechanism, the invention greatly increases the disassembly efficiency.

Preferably, each adjustment member further comprises a first adjustment seat formed with the fastening elements set, a first fine adjustment element disposed on the first adjustment seat, a second adjustment seat secured to the solder nozzles, and a second fine adjustment element secured to both the second adjustment seat and the first adjustment seat; and wherein the first fine adjustment element is configured to move along X-axis and the second fine adjustment element is configured to move along Y-axis respectively.

The soldering apparatus of the first aspect of the invention implements the following: the first fine adjustment element is configured to move along X-axis for fine adjustment of the solder nozzles, and the second fine adjustment element is configured to move along Y-axis for fine adjustment of the solder nozzles respectively. As an end, each solder nozzle can quickly, precisely move on a horizontal plane in an adjustment operation.

Preferably, the buffering member includes a plurality of adjustment grooves each corresponding to the bar, each adjustment groove having a plurality of buffering blocks corresponding to the solder nozzles respectively. As an end, each buffering block can precisely adjust position of each solder nozzle.

Preferably, the spooling mechanism includes a roller for driving at least one endless conveyor tape, and a buffering member for tensioning the endless conveyor tape.

Preferably, the number of the columns is four, the columns are disposed on four corners of the base, and a space is defined between the base and the movement mechanism for allowing the lower heating module, the spooling mechanism and the belt conveyor mechanism to dispose therein.

It is still another object of the invention to provide a soldering apparatus having a modularized solder nozzle module for quick assembly.

For achieving above and other objects, a third aspect of the invention provides a soldering apparatus comprising a rectangular base; a plurality of columns disposed on edges of the base; two lower heating modules each vertically disposed through the base; two spooling mechanisms each disposed on both the base and the lower heating module and including a roller for driving at least one endless conveyor tape, and a buffering member for tensioning the endless conveyor tape; a belt conveyor mechanism disposed on the base and under the spooling mechanisms; two movement mechanisms each moveably disposed on the columns at either side of the base; and two solder nozzle modules each having two sides supported by the movement mechanism and disposed through the spooling mechanism to be disposed on the lower heating module; wherein each solder nozzle comprises a frame secured to the movement mechanism and including at least two parallel bars, and a plurality of solder nozzles disposed under each bar; a plurality of positioning holes arranged in rows and disposed on each solder nozzle; and a plurality of adjustment members each disposed on the solder nozzle and besides the bar, each adjustment member including a fastening elements set secured to the positioning holes.

The soldering apparatus of the third aspect of the invention has the following advantages and benefits in comparison with the conventional art: a plurality of solder nozzle modules on the bar with the total number of the solder nozzles being double. Positions of the solder nozzles relative to the bar can be quickly adjusted because the fastening elements set is secured to the positioning holes. Further, the solder nozzle module can be assembled or disassembled quickly. Furthermore, a simple disassembly of the solder nozzle module can detach all solder nozzles from the solder nozzle module. In comparison with the prior art of detaching solder nozzles hanged from the movement mechanism, the invention greatly increases the disassembly efficiency.

Preferably, each adjustment member further comprises a first adjustment seat formed with the fastening elements set, a first fine adjustment element disposed on the first adjustment seat, a second adjustment seat secured to the solder nozzles, and a second fine adjustment element secured to both the second adjustment seat and the first adjustment seat; the first fine adjustment element is configured to move along X-axis and the second fine adjustment element is configured to move along Y-axis respectively; and the buffering member includes a plurality of adjustment grooves each corresponding to the bar, each adjustment groove having a plurality of buffering blocks corresponding to the solder nozzles respectively.

The soldering apparatus of the third aspect of the invention implements the following: the first fine adjustment element is configured to move along X-axis for fine adjustment of the solder nozzles, and the second fine adjustment element is configured to move along Y-axis for fine adjustment of the solder nozzles respectively. As an end, each solder nozzle can quickly, precisely move on a horizontal plane in an adjustment operation.

Preferably, the buffering member includes a plurality of adjustment grooves each corresponding to the bar, each adjustment groove having a plurality of buffering blocks corresponding to the solder nozzles respectively. As an end, each buffering block can precisely adjust position of each solder nozzle.

Preferably, the number of the columns is six, and a space is defined between the base and the movement mechanism for allowing the lower heating module, the spooling mechanism and the belt conveyor mechanism to dispose therein.

Preferably, the spooling mechanism includes a roller for driving at least one endless conveyor tape, and a buffering member for tensioning the endless conveyor tape.

The invention has the following advantages and benefits in comparison with the conventional art: Soldering apparatus and solder nozzle module thereof of the invention effects a plurality of solder nozzles mounted on a frame to facilitate disassembly of modularized solder nozzles, increase the number of the solder nozzles and density thereof, and fine adjust position of each solder nozzle. The invention has a particular application to solder nozzles having a pulse soldering electrode assembly so that performance and yield of a soldering operation are greatly increased.

The above and other objects, features and advantages of the invention will become apparent from the following detailed description taken with the accompanying drawings.

### BRIEF DESCRIPTION OF THE DRAWINGS

FIG. 1 is a perspective view of a soldering apparatus according to a first preferred embodiment of the invention;

FIG. 2 is a perspective view of FIG. 1 with a top, a lower framework and four posts removed;

FIG. 3 is an exploded view of FIG. 2;

FIG. 4 is a perspective view of the solder nozzle module;

FIG. 5 is an exploded perspective view of FIG. 4;

FIG. 6 is an exploded view of FIG. 4;

FIG. 7 is a top view of FIG. 4;

FIG. 8 is a perspective view of a buffering member of a spooling mechanism;

FIG. 9 is an exploded view of FIG. 8;

FIG. 10 is a perspective view of a soldering apparatus according to a second preferred embodiment of the invention;

FIG. 11 is a perspective view of a soldering apparatus according to a third preferred embodiment of the invention;

FIG. 12 is a perspective view of FIG. 11 with a top, a lower framework and four posts removed;

FIG. 13 is an exploded view of the solder nozzle modules, the movement mechanisms, the lower heating modules, the spooling mechanisms, the belt conveyor mechanism, and the base shown in FIG. 12; and

FIG. 14 is a top view of the solder nozzle modules of FIG. 12.

### DETAILED DESCRIPTION OF THE INVENTION

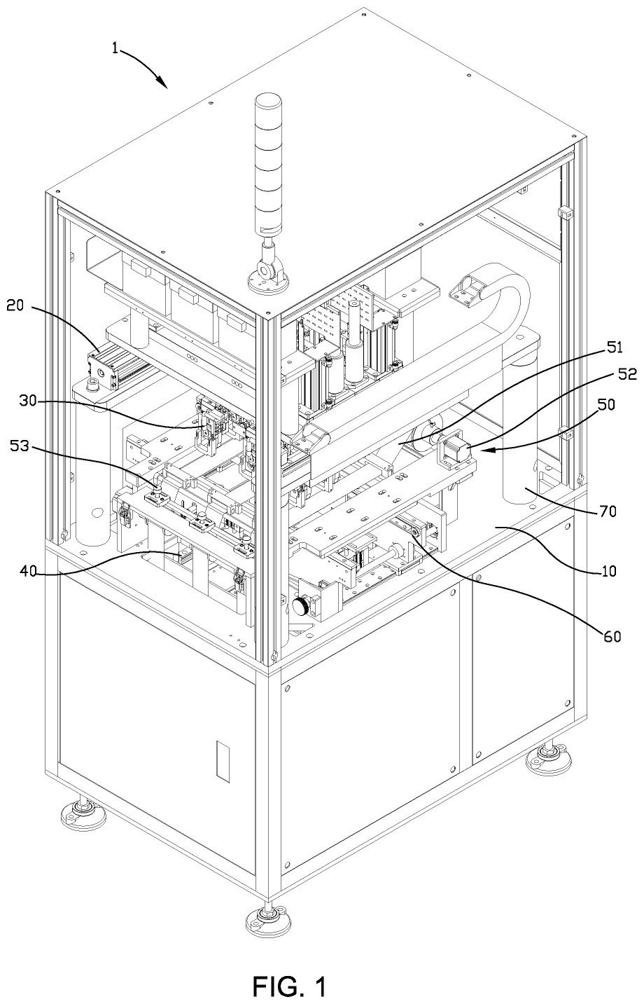

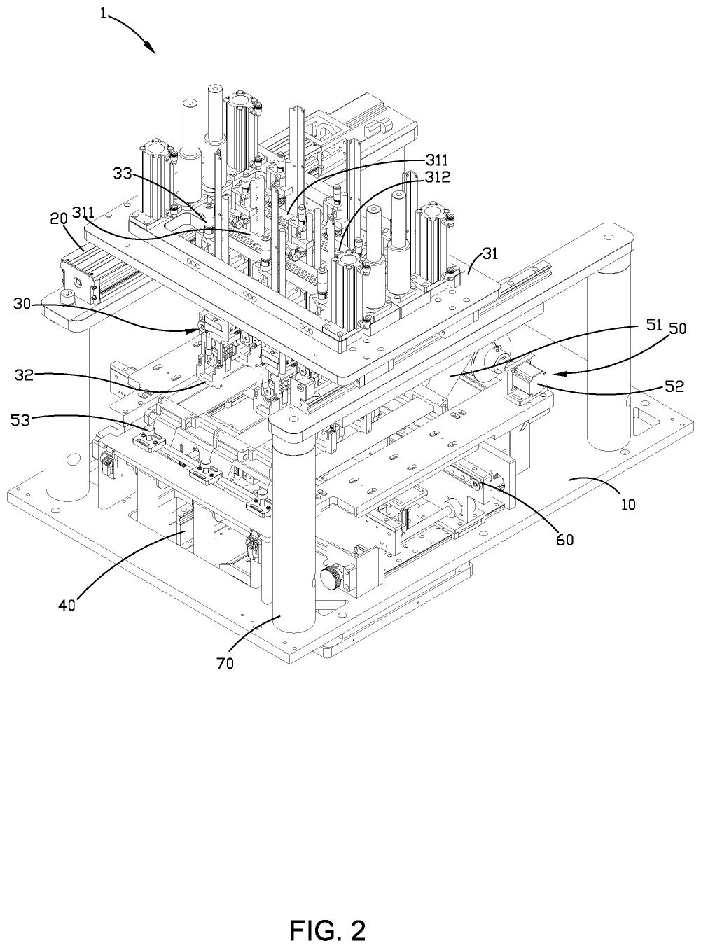

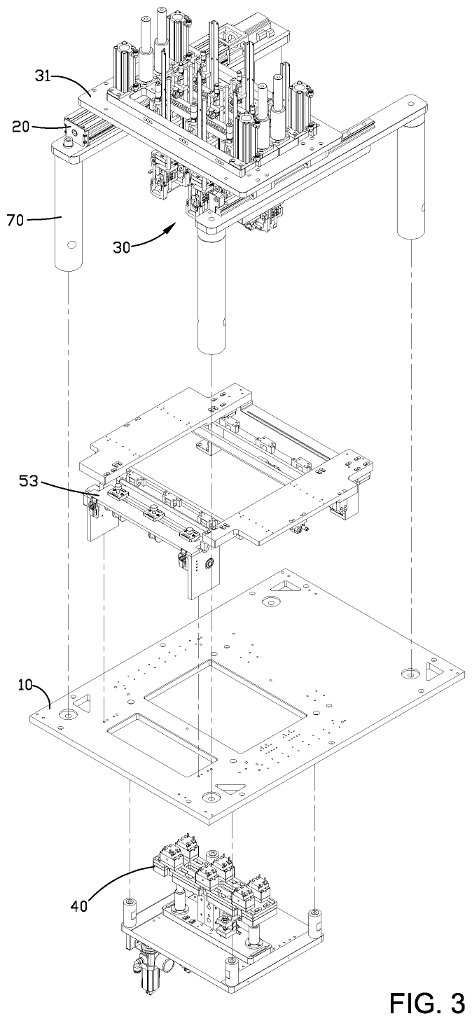

Referring to FIGS. 1 to 9, a soldering apparatus 1 in accordance with the invention is shown in which FIG. 1 is a perspective view of a soldering apparatus according to a first preferred embodiment of the invention, FIG. 2 is a perspective view of FIG. 1 with a top, a lower framework and four posts removed, and FIG. 3 is an exploded view of FIG. 2. The invention is discussed in detail below.

The soldering apparatus 1 comprises a rectangular base 10, a plurality of (e.g., four) columns 70 proximate four corners of the base 10 respectively, a lower heating module 40 vertically mounted through the base 10, a spooling mechanism 50 mounted on both the base 10 and the lower heating module 40, a belt conveyor mechanism 60 mounted on the base 10 and under the spooling mechanism 50, a movement mechanism 20 moveably mounted on the two columns 70 at one side and the two columns 70 at the other side, and a solder nozzle module 30 having two sides supported by the movement mechanism 20 and mounted through the spooling mechanism 50 to be disposed on the lower heating module 40. A space is defined between the base 10 and the movement mechanism 20 for allowing the lower heating module 40, the spooling mechanism 50 and the belt conveyor mechanism 60 to dispose therein. As shown in FIG. 3 specifically, a movement of the movement mechanism 20 may move the solder nozzle module 30 relative to and above the base 10.

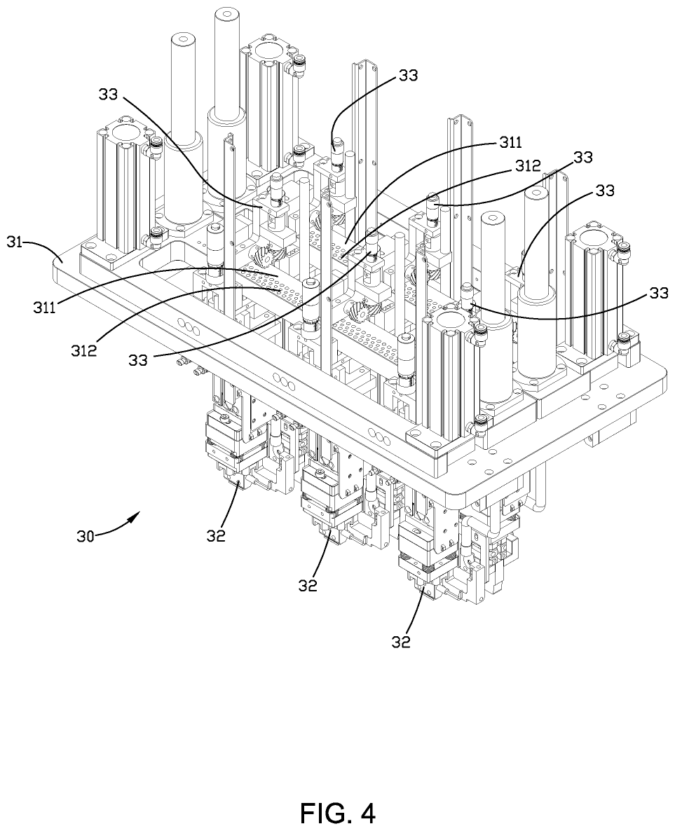

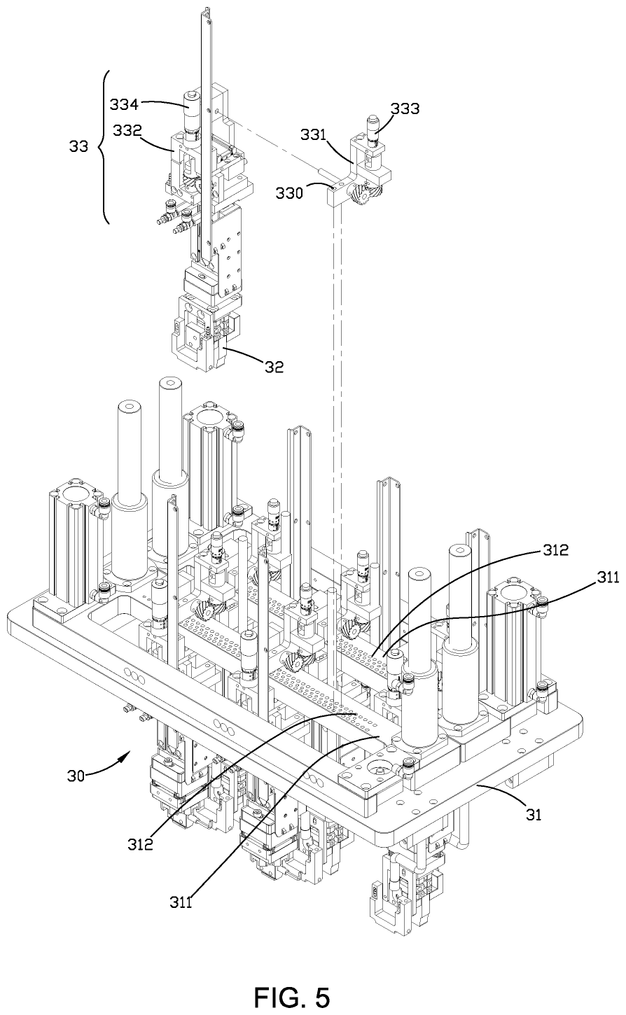

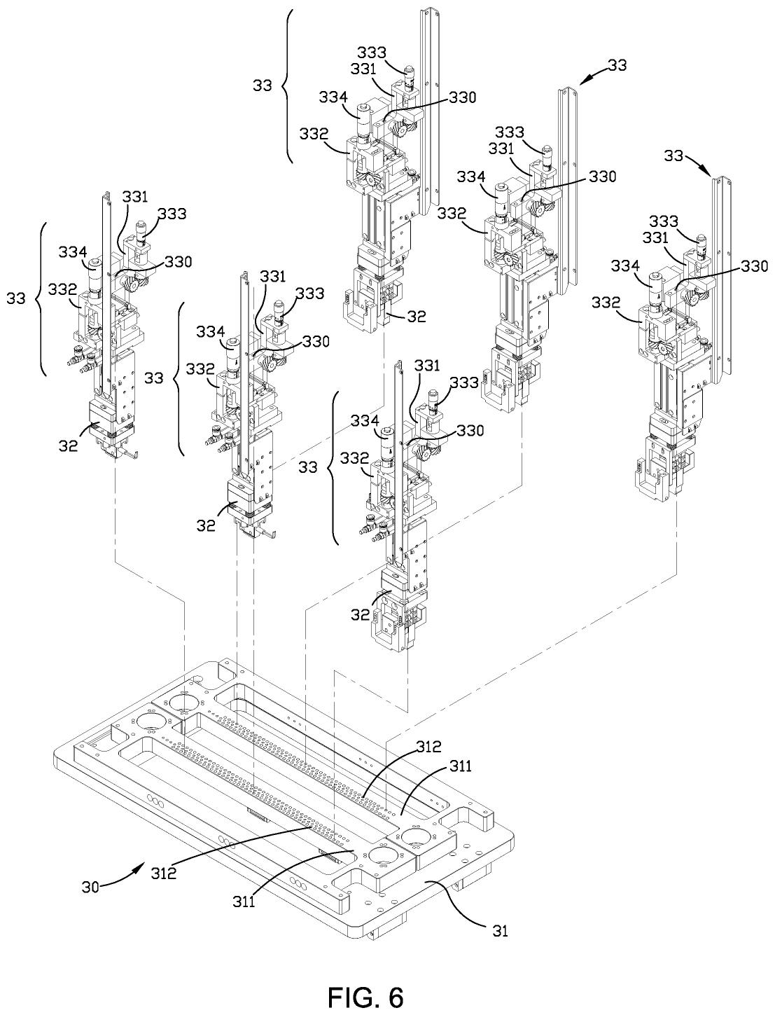

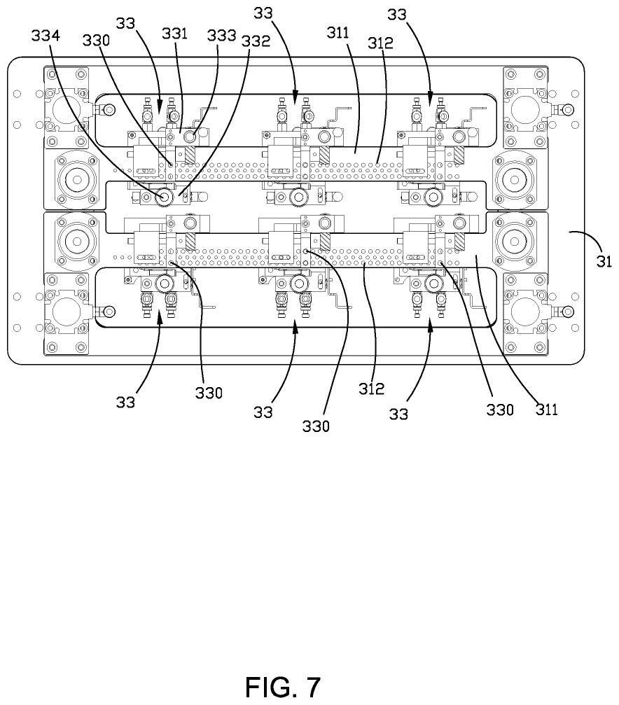

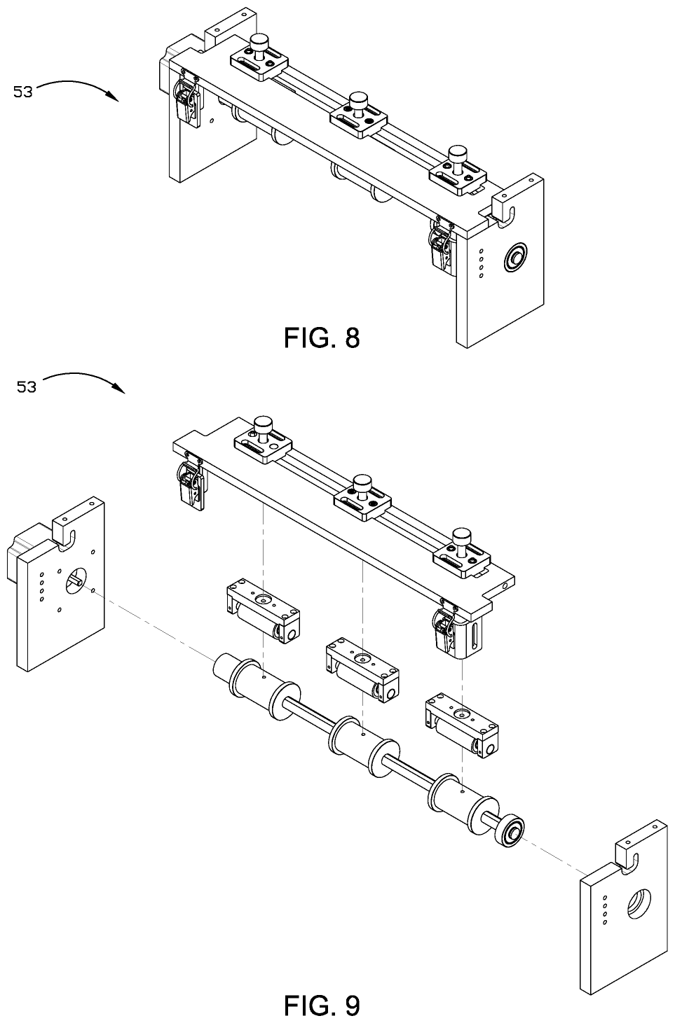

As shown in FIGS. 4 to 9 specifically, the invention is further discussed in which FIG. 4 is a perspective view of the solder nozzle module, FIG. 5 is an exploded perspective view of FIG. 4, FIG. 6 is an exploded view of FIG. 4, FIG. 7 is a top view of FIG. 4, FIG. 8 is a perspective view of a buffering member of a spooling mechanism, and FIG. 9 is an exploded view of FIG. 8.

The solder nozzle module 30 includes a frame 31 secured to the movement mechanism 20 and having two parallel bars 311, and a plurality of solder nozzles 32 mounted under the bars 311. The solder nozzle 32 has a pulse soldering electrode assembly. The solder nozzle 32 is known in the art and thus a detailed description thereof is omitted herein for the sake of brevity.

The solder nozzle module 30 further comprises a plurality of rows of positioning holes 312 disposed on the bars 311, a plurality of adjustment members 33 each disposed on the solder nozzle 32 and besides the bar 311, the adjustment member 33 including a fastening element 330 selectively sited on the positioning holes 312 so as to alter the position between the bar 311 and the fastening element 330, a first adjustment seat 331 formed with the fastening element 330, a first fine adjustment element 333 provided on the first adjustment seat 331, a second adjustment seat 332 secured to the solder nozzles 32, and a second fine adjustment element 334 secured to both the second adjustment seat 332 and the first adjustment seat 331. The first fine adjustment element 333 may move along X-axis and the second fine adjustment element 334 may move along Y-axis respectively.

In the first embodiment, three solder nozzles 32 are provided on each of the two bars 311, i.e., the number of the solder nozzles 32 being six. But the number of the solder nozzles 32 may be varied in other embodiments depending on applications. Thus, the solder nozzles 32 may be arranged in a plurality of rows relative to the frame 31. This has the following benefits: the number of the solder nozzles 32 and density thereof are increased greatly.

Further, positions of the solder nozzles 32 relative to the bar 311 may be quickly adjusted because the fastening element 330 are selectively sited to the positioning holes 312. Furthermore, the solder nozzle module 30 can be assembled or disassembled quickly.

In addition, the solder nozzle module 30 may activates both the first fine adjustment element 333 and the second fine adjustment element 334 to fine adjust the solder nozzle 32 in X-axis direction and Y-axis direction respectively. As a result, each solder nozzle 32 can quickly, precisely move on a horizontal plane in an adjustment operation.

The spooling mechanism 50 includes a roller 52 for driving three endless conveyor tapes 51, and a buffering member 53 for tensioning the tapes 51.

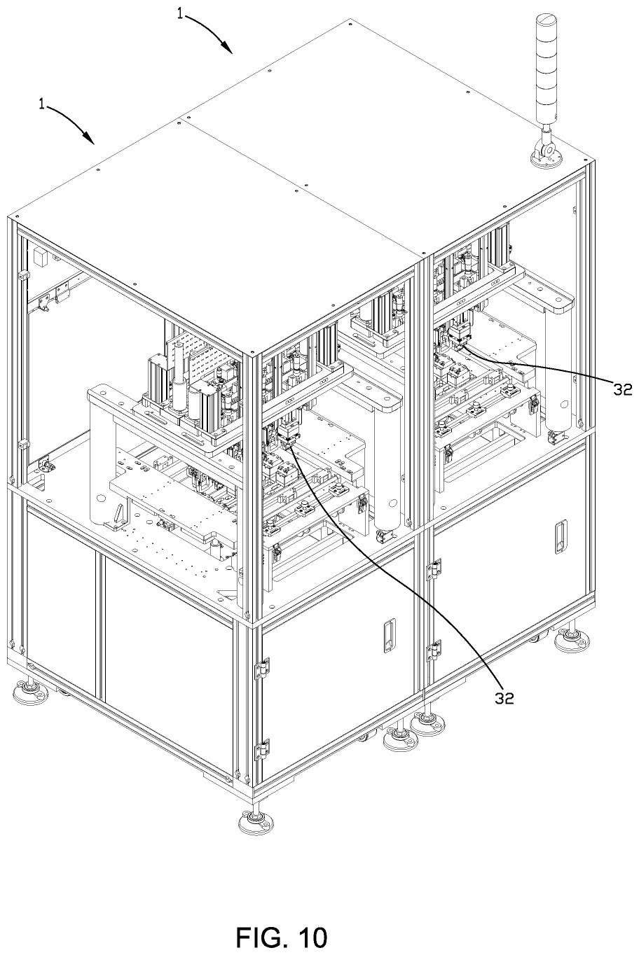

Referring to FIG. 10, a soldering apparatus 1 in accordance with a second preferred embodiment of the invention is shown. The characteristics of the second preferred embodiment are substantially the same as that of the first preferred embodiment except the following: two soldering apparatuses 1 are operatively connected together and thus the total number of solder nozzle 32 is double.

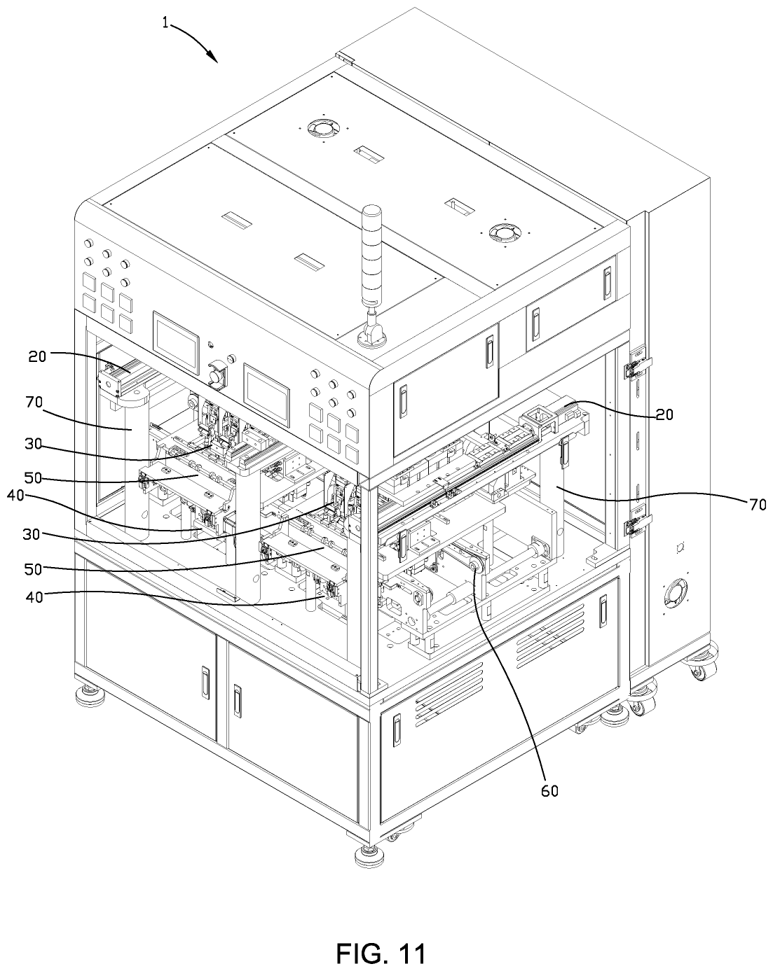

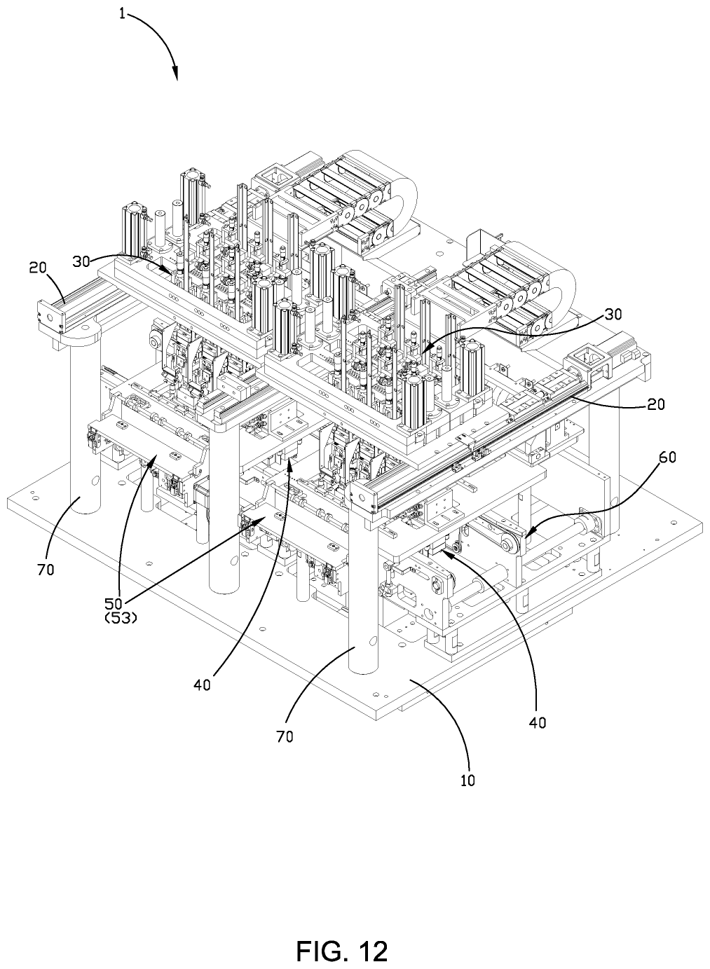

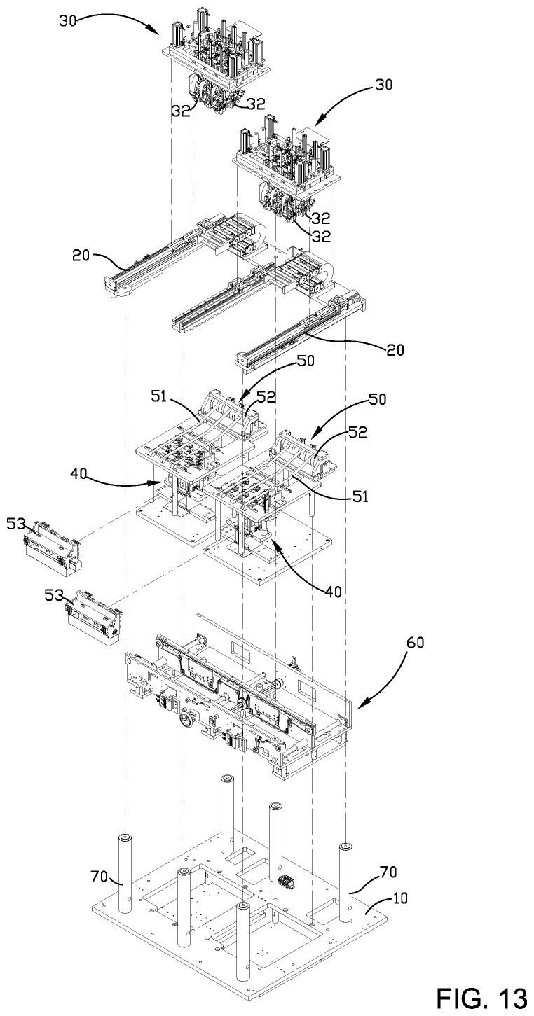

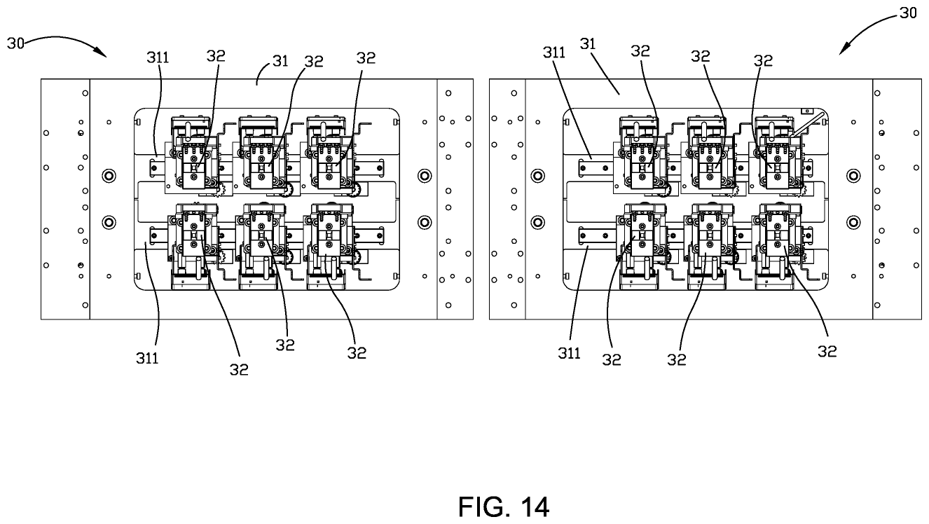

Referring to FIGS. 11 to 14, a soldering apparatus 1 in accordance with a third preferred embodiment of the invention is shown in which FIG. 11 is a perspective view of a soldering apparatus according to the third preferred embodiment of the invention, FIG. 12 is a perspective view of FIG. 11 with a top, a lower framework and four posts removed, FIG. 13 is an exploded view of the solder nozzle modules, the movement mechanisms, the lower heating modules, the spooling mechanisms, the belt conveyor mechanism, and the base, and FIG. 14 is a top view of the solder nozzle modules of FIG. 11. The characteristics of the third preferred embodiment are substantially the same as that of the first preferred embodiment except the following:

The soldering apparatus 1 comprises a rectangular base 10, a plurality of (e.g., six) columns 70 arranged in three rows in which two columns 70 are proximate two corners at one side of the base 10, another two columns 70 are proximate two corners at the other side of the base 10, and still another two columns 70 are proximate edges of the base 10 between the other four columns 70, two lower heating modules 40 each vertically mounted through the base 10, two spooling mechanisms 50 each mounted on both the base 10 and the lower heating module 40, a belt conveyor mechanism 60 mounted on the base 10 and under the spooling mechanisms 50, two movement mechanisms 20 in which one is moveably mounted on the two columns 70 at one side and the other is moveably mounted on the two columns 70 at the other side, and two solder nozzle modules 30 each having two sides supported by the movement mechanism 20 and mounted through the spooling mechanism 50 to be disposed on the lower heating module 40.

A space is defined between the base 10 and the movement mechanisms 20 for allowing the lower heating modules 40, the spooling mechanisms 50 and the belt conveyor mechanism 60 to dispose therein.

Further, each of the two solder nozzle modules 30 has two parallel bars 311 each having three solder nozzles 32, i.e., the total number of the solder nozzles 32 being 12. Thus, the total number of the solder nozzles 32 is double. It has the advantages of meeting the needs of production line, increasing the number of soldering points finished per unit time, and greatly increasing efficiency.

As discussed in the first, second, and third embodiments, the invention has the following characteristics and advantages: The solder nozzle module 30 is novel and its solder nozzles 32 are modularized and mounted on the frame 31. It can facilitate assembly or disassembly. The number of the solder nozzles 32 and density thereof are increased greatly. Further, positions of the solder nozzles 32 relative to the bar 311 may be quickly, precisely adjusted.

While the invention has been described in terms of preferred embodiments, those skilled in the art will recognize that the invention can be practiced with modifications within the spirit and scope of the appended claims.

What is claimed is:

1. A solder nozzle module disposed on a movement mechanism of a soldering apparatus, comprising:
a frame secured to the movement mechanism and including at least two parallel bars, and a plurality of solder nozzles disposed under each bar;
a plurality of positioning holes arranged in rows and disposed on each bar; and
a plurality of adjustment members each disposed on the solder nozzle and besides the bar, each adjustment member including a fastening elements selectively sited to the positioning holes so as to alter the position between the bar and the fastening element.

2. The solder nozzle module of claim 1, wherein each adjustment member further comprises a first adjustment seat formed with the fastening element, a first fine adjustment element disposed on the first adjustment seat, a second adjustment seat secured to the solder nozzles, and a second fine adjustment element secured to both the second adjustment seat and the first adjustment seat; and wherein the first fine adjustment element is configured to move along X-axis and the second fine adjustment element is configured to move along Y-axis respectively.

3. The solder nozzle module of claim 1, wherein each solder nozzle includes a pulse soldering electrode assembly.

4. A soldering apparatus comprising:
a rectangular base;
a plurality of columns disposed on edges of the base;
a lower heating module vertically disposed through the base;
a spooling mechanism disposed on both the base and the lower heating module;
a belt conveyor mechanism disposed on the base and under the spooling mechanism;
a movement mechanism moveably disposed on the columns at one side of the base and the columns at the other side of the base; and
a solder nozzle module having two sides supported by the movement mechanism and disposed through the spooling mechanism to be disposed on the lower heating module;
wherein the solder nozzle module includes:
a frame secured to the movement mechanism and including at least two parallel bars, and a plurality of solder nozzles disposed under each bar;
a plurality of positioning holes arranged in rows and disposed on each bar; and
a plurality of adjustment members each disposed on the solder nozzle and besides the bar, each adjustment member including a fastening element selectively sited to the positioning holes.

5. The soldering apparatus of claim 4, wherein each adjustment member further comprises a first adjustment seat formed with the fastening elements set, a first fine adjustment element disposed on the first adjustment seat, a second adjustment seat secured to the solder nozzles, and a second fine adjustment element secured to both the second adjustment seat and the first adjustment seat; and wherein the first fine adjustment element is configured to move along X-axis and the second fine adjustment element is configured to move along Y-axis respectively.

6. The soldering apparatus of claim 4, wherein the spooling mechanism includes a roller for driving at least one endless conveyor tape, and a buffering member for tensioning the endless conveyor tape.

7. The soldering apparatus of claim 4, wherein the number of the columns is four, the columns are disposed on four corners of the base, and a space is defined between the base and the movement mechanism.

8. A soldering apparatus comprising:
a rectangular base;
a plurality of columns disposed on edges of the base;
two lower heating modules each vertically disposed through the base;
two spooling mechanisms each disposed on both the base and the lower heating module and including a roller for driving at least one endless conveyor tape, and a buffering member for tensioning the endless conveyor tape;
a belt conveyor mechanism disposed on the base and under the spooling mechanisms;
two movement mechanisms each moveably disposed on the columns at either side of the base; and
two solder nozzle modules each having two sides supported by the movement mechanism and disposed through the spooling mechanism to be disposed on the lower heating module;
wherein each solder nozzle module comprises:
a frame secured to the movement mechanism and including at least two parallel bars, and a plurality of solder nozzles disposed under each bar;
a plurality of positioning holes arranged in rows and disposed on each solder nozzle; and
a plurality of adjustment members each disposed on the solder nozzle and besides the bar, each adjustment member including a fastening element selectively sited to the positioning holes.

9. The soldering apparatus of claim 8, wherein each adjustment member further comprises a first adjustment seat formed with the fastening elements set, a first fine adjustment element disposed on the first adjustment seat, a second adjustment seat secured to the solder nozzles, and a second fine adjustment element secured to both the second adjustment seat and the first adjustment seat; wherein the first fine adjustment element is configured to move along X-axis and the second fine adjustment element is configured to move along Y-axis respectively; and wherein the buffering member includes a plurality of adjustment grooves each corresponding to the bar, each adjustment groove having a plurality of buffering blocks corresponding to the solder nozzles respectively.

10. The soldering apparatus of claim 8, wherein the number of the columns is six, and a space is defined between the base and the movement mechanism.

11. The soldering apparatus of claim 8, wherein the spooling mechanism includes a roller for driving at least one endless conveyor tape, and a buffering member for tensioning the endless conveyor tape.
